(19) United States
(12) Patent Application Publication
(10) Pub. No.: US 2016/0377677 A1
(43) Pub. Date: Dec. 29, 2016

(54) CHIP AND METHOD FOR TESTING A PROCESSING COMPONENT OF A CHIP

(71) Applicant: Infineon Technologies AG, Neubiberg (DE)

(72) Inventors: Daniel TILLE, Unterhaching (DE); Ulrike PFANNKUCHEN, Munich (DE); Marcus JANKE, Munich (DE)

(21) Appl. No.: 15/191,553

(22) Filed: Jun. 24, 2016

(30) Foreign Application Priority Data
Jun. 24, 2015 (DE) 102015110144.0

(51) Int. Cl. G01R 31/3177; G01R 31/317

(52) U.S. Cl. CPC G01R 31/3177; G01R 31/3172

(57) ABSTRACT

In accordance with one embodiment, a chip is provided which includes an interface configured to receive test data and masking data, a processing component having a plurality of scan chains. Each scan chain is configured to generate a test response on the basis of a processing of the test data. The chip further includes a compression circuit configured to compress the test responses generated by the scan chains to form a compressed test response, and a signature generating circuit configured to generate a signature on the basis of the compressed test response, depending on whether the masking data specify that the compressed test response is to be masked.

### CROSS-REFERENCE TO RELATED APPLICATION

This application claims priority to German Patent Application Serial No. 10 2015 110 144.0, which was filed Jun. 24, 2015, and is incorporated herein by reference in its entirety.

### TECHNICAL FIELD

Various embodiments relate generally to chips and methods for testing a processing component of a chip.

### BACKGROUND

Manufactured chips are usually tested to sort out defective chips. Testing leads to various costs such as costs for the hardware on the chip required for the testing as well as the costs of the actual test procedure, which normally depend on the test duration. It is desirable to keep these costs low. On the other hand, it is desirable to have tests which cover a wide range of defects that a chip may have.

### SUMMARY

In accordance with one embodiment, a chip is provided which includes an interface configured to receive test data and masking data, a processing component having a plurality of scan chains. Each scan chain is configured to generate a test response on the basis of a processing of the test data. The chip further includes a compression circuit configured to compress the test responses generated by the scan chains to form a compressed test response, and a signature generating circuit configured to generate a signature on the basis of the compressed test response, depending on whether the masking data specify that the compressed test response is to be masked.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a chip with a 2-pin test architecture;

FIG. 2 shows a chip with a 1-pin test architecture;

FIG. 3 shows a chip in accordance with one embodiment;

FIG. 4 shows a flow diagram illustrating a method for testing a processing component of a chip;

FIG. 5 shows a test arrangement in accordance with one embodiment; and

FIG. 6 shows one example of a test data stream, a stream for expected compressed test responses, a masking data stream and also a combined test input stream.

### DESCRIPTION

The following detailed description refers to the accompanying figures that show details and embodiments. These embodiments are described in sufficient detail that the person skilled in the art can implement the invention. Other embodiments are also possible and the embodiments may be modified structurally, logically and electrically, without departing from the subject matter of the invention. The various embodiments are not necessarily mutually exclusive, rather various embodiments may be combined with one another to give rise to new embodiments. In the context of this description, the terms “connected” and “coupled” are used to describe a direct or indirect connection and a direct or indirect coupling.

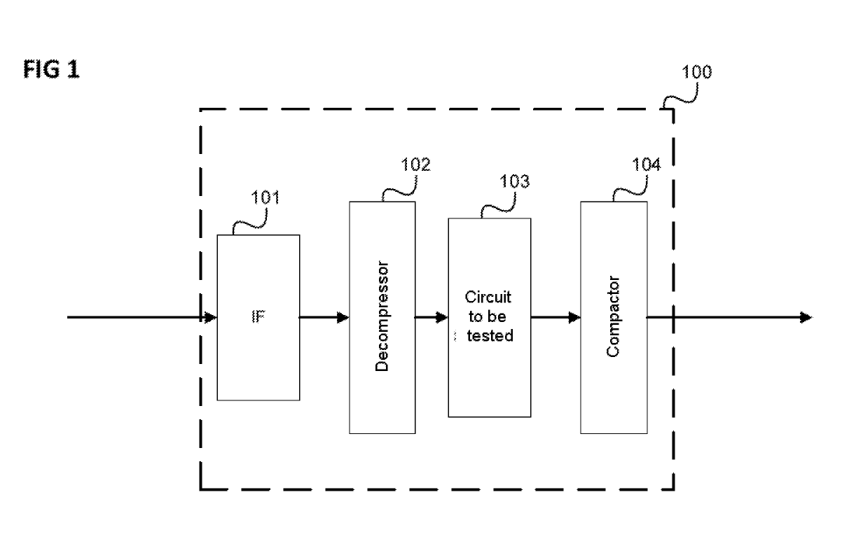

One example of architecture for carrying out a scan test by means of two pins of a chip is described below with reference to FIG. 1.

FIG. 1 shows a chip 100 with a 2-pin test architecture.

The chip contains a serial interface 101 via which the scan data (in other words test data or input test data, for example containing a plurality of test patterns) can be fed to the chip 100 for testing the chip 100 via a first pin in the form of a stream having a width of 1 bit. The interface 101 feeds the test data to a decompressor 102, which decompresses the test data and feeds the decompressed test data to a circuit 103 to be tested, i.e. a component of the chip 100 which is intended to be tested by means of the test data. The circuit 103 to be tested processes the test data, e.g. by a plurality of scan chains which are loaded in a shift phase with the values of a decompressed test pattern.

The circuit to be tested contains for example a plurality of scan chains. The test data on the basis of which all flip-flops of all scan chains are loaded once in order to be processed by one or more capture phases are referred to as a test pattern hereinafter. The procedure of loading all flip-flops of all scan chains once, processing their values by a capture phase (which may contain one or more capture iterations) and outputting the values of the flip-flops is referred to as a test cycle hereinafter.

Test data fed to the chip via the interface 101 for a test cycle typically does not explicitly contain the values for the flip-flops of all scan chains. Instead, the decompressor 102 generates these values from a compressed test pattern, e.g. by filling the flip-flops with random values that are unimportant for the current test cycle (in other words with “don't care” bits).

After the processing of the values loaded into the flip-flops by means of a capture phase (i.e. at the end of a test cycle), the resulting values are shifted out of the circuit 103 to be tested and are fed to a compactor 104. The compactor 104 contains for example the functionality of an XOR (exclusive OR) gate (i.e. exclusive OR) which receives the output of the scan chains (shifted into the XOR gate bit by bit). The compactor 104 generates a scan output stream having a width of 1 bit which the chip 100 outputs via a second pin. The scan output data stream can then be compared with reference data (e.g. “golden values”) by a tester (e.g. a test device). Such an actual-setpoint comparison is typically carried out for each test cycle.

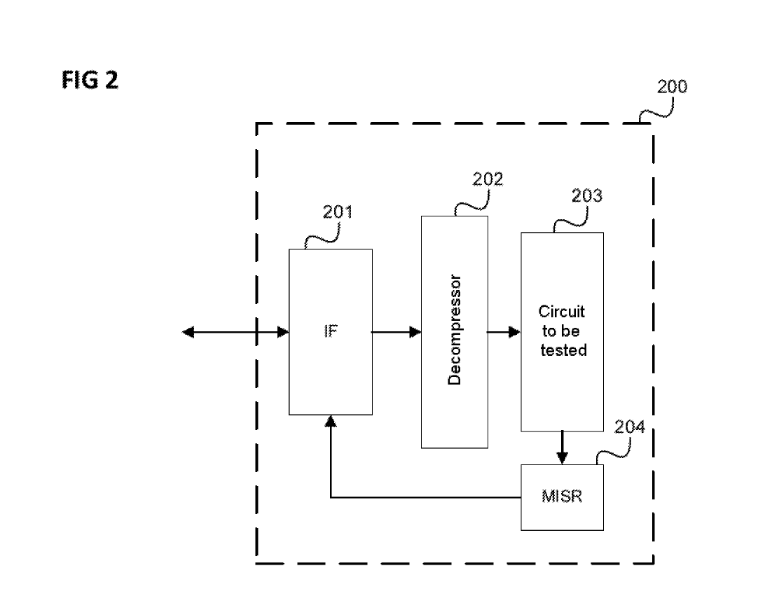

However, in devices such as smart cards or other products having a small number of pins and e.g. a serial interface having only one pin, there may be only one pin available for the test. Furthermore, even if two or more pins are available, the use of a single pin for testing may be desirable since this may increase the test parallelism and thus reduce test costs. This may be achieved for example by the architecture illustrated in FIG. 2.

FIG. 2 shows a chip 200 with a 1-pin test architecture.

In a manner similar to the chip 100 from FIG. 1, the chip 200 contains an interface 201 for receiving input test data via a first pin, a decompressor 202 and a circuit 203 to be tested.

Instead of the compactor 104 which generates a test output stream and outputs it via a second pin, the chip contains a MISR (multiple input signature register) 204. The circuit 203 to be tested outputs test responses of the scan chains (e.g. the status of each of at least a subset of the flip-flops of the scan chains after the capture phase) to the MISR (multiple input signature register) 204, which generates a signature from the test responses step by step.

After the test (which may contain a plurality of test cycles, wherein the MISR accumulates the signature for each test cycle) has been concluded and the MISR 204 has generated a signature on the basis of the results of all test responses, it outputs the generated signature via the interface 101 and the first pin. The generated signature may then be compared with a reference signature (golden signature) in order to check whether the circuit 203 to be tested has passed or failed the test.

However, some circuits yield unknown values (so-called X values) during the scan test in the test responses. Reasons for this may be:
faulty isolation of macros or SFRs (Special Function Registers) and
timing exceptions (e.g. false or multicycle paths).

The compression of the test responses by a MISR is not available for such circuits. A single X value could lead to an erroneous signature and a comparison of the signature with the golden signature would thus indicate a defect even for error-free circuits to be tested. Therefore, a scan test is not possible in the 1-pin test as in FIG. 2 or the X values must be avoided by means of complex hardware changes.

A circuit which generates X values can be tested by the 2-pin test illustrated in FIG. 1. The positions of all X values in the scan output stream can be calculated by an ATPG (automatic test pattern generating) tool. Therefore, the comparison with the golden value can be deactivated at the tester with the use of the 2-pin test for these positions in the scan output stream. As mentioned above, in specific devices there may be only one pin available, however, or only one pin is intended to be used for cost reasons.

One possibility for enabling testing for a circuit which generates X values using only one pin is to temporarily store the stream of test responses (or else the stream of compressed test responses) and to output it in an offset manner. By way of example, instead of the MISR 204, a temporary buffer may be provided which temporarily stores the test responses and outputs them at a point in time at which no scan data are fed to the chip 100 via the interface 201. However, the temporary buffer typically leads to high additional costs with regard to chip area, and the offset outputting of the results requires a complex communication protocol at the tester.

A chip is described below which enables a circuit of the chip which generates X values to be tested without such a temporary buffer.

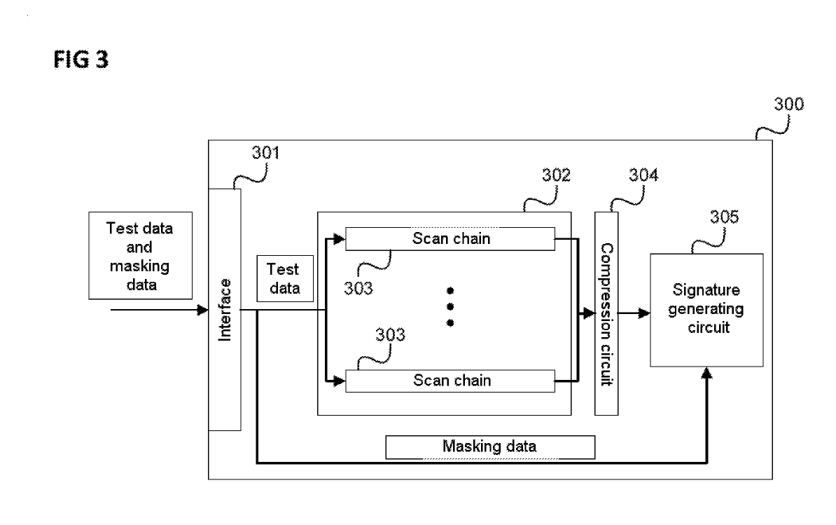

FIG. 3 shows a chip 300 in accordance with one embodiment.

The chip 300 includes an interface 301 configured to receive test data and masking data, and a processing component 302 having a plurality of scan chains 303, wherein each scan chain is configured to generate a test response on the basis of a processing of the test data.

The chip 300 furthermore includes a compression circuit 304 (e.g. a compactor) configured to compress the test responses generated by the scan chains 303 to form a compressed test response.

Moreover, the chip 300 includes a signature generating circuit 305 configured to generate a signature on the basis of the compressed test response, depending on whether the masking data specify that the compressed test response is to be masked.

In other words, test responses from a plurality of scan chains are combined (for example by an XOR combination), such that, for example for each clock cycle of the clock with which the scan chains are clocked, i.e. data are shifted into the scan chains and out of the scan chains, a compressed test response (e.g. a bit) is generated. Such a bit, for example if it is expected that one of the scan chains for generating the bit has supplied an X value, can then be blocked out (or masked), i.e. the bit can be prevented from influencing the determination of a signature (for example by a MISR). In this case, the blocking out (or masking) takes place after the compressing of the test responses and can be performed with bit accuracy. In other words, in accordance with one embodiment, the test responses of the scan chains are not individually blocked out, nor are scan chains (over a plurality of clock cycles, e.g. an entire test cycle) masked sweepingly, rather the individual bits are masked in the compressed test response.

Since the chip outputs a signature which can be used for test evaluation (e.g. evaluation of a pass/fail criterion), a chip having a circuit to be tested which generates X values can be tested by means of a 1-pin test.

In accordance with one embodiment, each scan chain is configured to generate a sequence of test responses on the basis of the processing of the test data, and the compression circuit is configured to compress the sequences of test responses generated by the scan chains to form a sequence of compressed test responses.

By way of example, the masking data specify which compressed test responses of the sequence of compressed test responses are to be masked, and the signature generating circuit is configured to generate the signature on the basis of the compressed test responses apart from those compressed test responses of the sequence of compressed test responses which are to be masked.

In accordance with one embodiment, the signature generating circuit is configured to generate the signature on the basis of the compressed test responses which are not to be masked and predefined values for those compressed test responses of the sequence of compressed test responses which are to be masked.

The chip includes for example a masking circuit configured to mask the compressed test response if it is to be masked in accordance with the masking data.

Masking a test response includes for example overwriting the test response with a predefined value. Alternatively, a test response could be masked by deactivating the clock of the signature generating unit (e.g. the MISR clock) at the point in time at which the test response is fed to the signature generating circuit.

In accordance with one embodiment, the chip has a security mode in which the masking circuit is configured to mask the compressed test response independently of the masking data.

The chip includes for example a security circuit which is configured to deactivate the security mode when a predefined key is input, such that the masking circuit masks the compressed test response depending on the masking data.

In accordance with one embodiment, the chip includes a detection circuit configured to detect whether the security mode is deactivated even though the chip is not in a test mode, and to output an alarm signal if the security mode is deactivated even though the chip is not in a test mode.

In accordance with one embodiment, the masking circuit is configured to mask predefined compressed test responses of the compressed test responses (which occur for example in predefined test cycles) independently of the masking data. Specific, for example security-relevant, data can thus be protected.

In accordance with one embodiment, the chip includes a control circuit configured to deactivate the processing of a compressed test response for generating a signature if the compressed test response is to be masked.

Each test response is a bit, for example.

Compressing the test responses is for example an XOR combination of the test responses, such that the compressed test response is a test response bit.

The masking data include, for example for each test response bit of a sequence of test response bits, a bit which indicates whether the test response bit is to be masked.

In accordance with one embodiment, the scan chains are configured to process the test data during a plurality of clock cycles of a clock signal and to output a test response for each clock cycle of the clock signal.

The compression circuit is configured for example to compress, for each clock cycle of the clock signal, the test responses output by the scan chains for the clock cycle to form a compressed test response.

In accordance with one embodiment, the interface includes a pin and is configured to receive the test data and masking data via the pin and to output the signature via the pin.

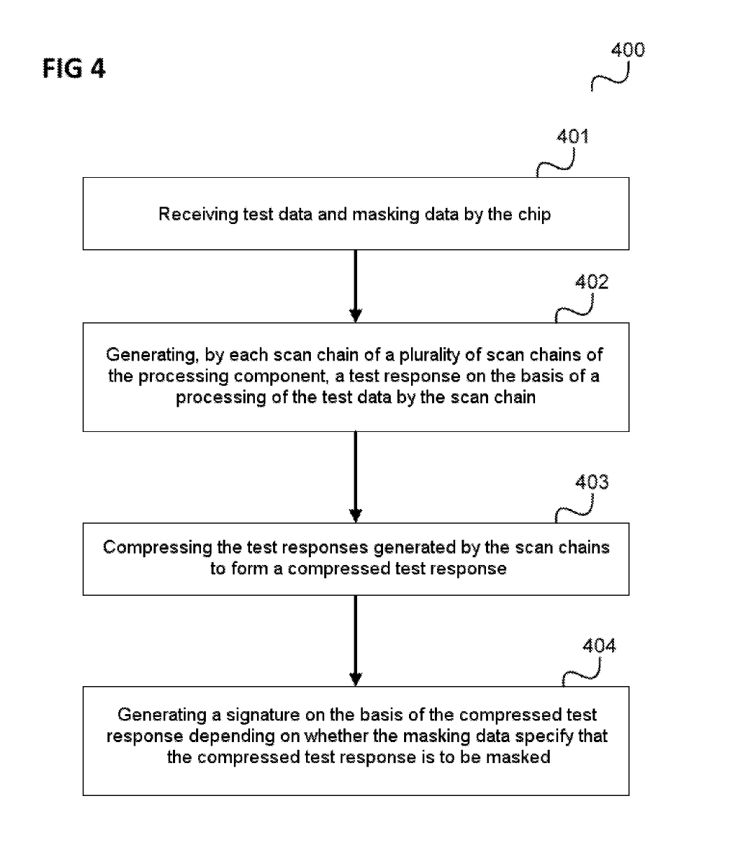

In accordance with one embodiment, a method for testing a processing component of a chip as illustrated in FIG. 4 is provided.

FIG. 4 shows a flow diagram 400.

In 401, the chip receives test data and masking data.

In 402, each scan chain of a plurality of scan chains of the processing component generates a test response on the basis of a processing of the test data by the scan chain.

In 403, the test responses generated by the scan chains are compressed to form a compressed test response.

In 404, a signature is generated on the basis of the compressed test response depending on whether the masking data specify that the compressed test response is to be masked.

Embodiments are explained in greater detail below.

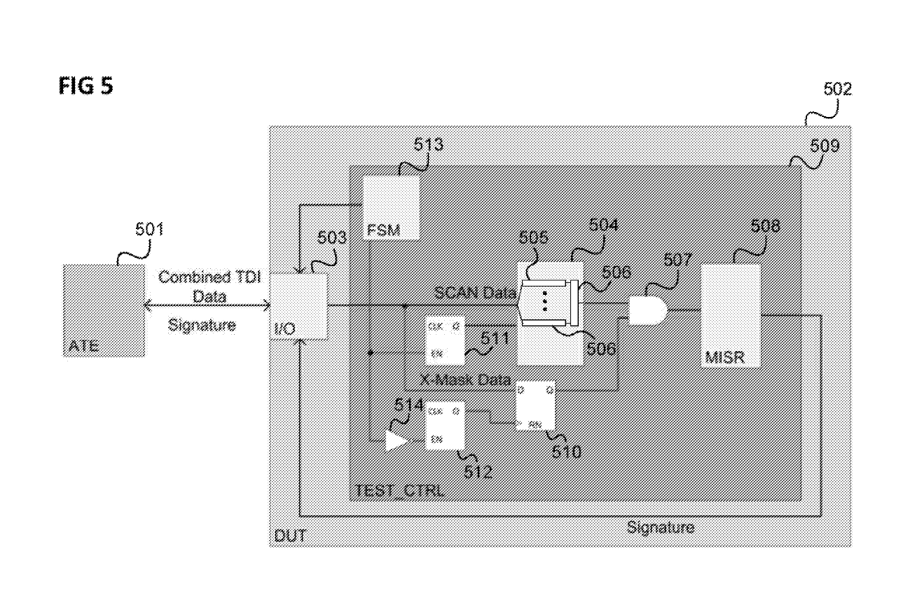

FIG. 5 shows a test arrangement 500 in accordance with one embodiment.

The test arrangement 500 includes a tester (Automatic Test Equipment, ATE) 501 and a chip 502 (which, in this example, can be regarded as a device to be tested (Device under Test, DUT)).

The chip 502 includes an interface 503 via which the tester 501 can feed test data to the chip 502 and can receive from the chip 502 a signature generated for the test data.

The chip 502 includes a circuit to be tested. The circuit 504 to be tested includes a plurality of scan chains 505, and also a compactor 506, for example in the form of an XOR gate that compresses the test responses of the scan chains to form a compressed test response.

If the scan chains 505 are loaded with test data, the test data (in a capture phase) are processed and the results of the processing are stored in the scan chains 505. The results of the processing are then shifted out of the scan chains 505 bit by bit and compressed by the XOR gate 506. Consequently, for each clock cycle of a clock signal with which the scan chains 505 are clocked, each scan chain outputs a 1-bit test response, which are compressed by the XOR gate 506 to form a bit. In this case, an X value of a test response of a scan chain leads to an X value of the compressed test response.

The 1-bit test response is fed to an AND gate 507, by means of which the 1-bit test response can be masked before it is fed to a MISR 508. For this purpose, the positions—calculated beforehand by an ATPG tool for example—of the X values in the test response streams of the scan chains are used to mask the X values for the signature calculation by the MISR 508. As a result, the signature becomes deterministic and can be used for example for a pass/fail criterion in the at-speed scan test.

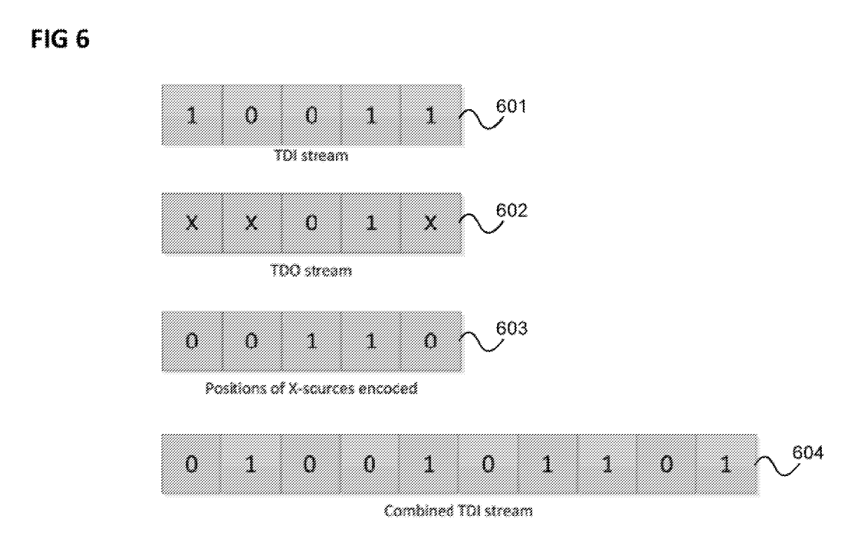

In accordance with one embodiment, firstly a preprocess is carried out beforehand, which is explained below on the basis of the example illustrated in FIG. 6.

FIG. 6 shows one example of a test data stream 601 (TDI stands for test data input), a stream for expected (correct) compressed test responses 602 (i.e. an expected scan output data stream or expected TDO (test data output stream), a masking data stream 603 and a combined test input stream 604.

The test data calculated by the ATPG tool and the expected test responses serve as a basis for the generation of the test input stream 604.

Firstly, the positions of the X values are extracted from the TDO data stream. If an ‘X’ is expected as compressed test response for a clock cycle, an ‘0’ is inserted at the corresponding location of the masking data stream. By contrast, if a deterministic value (‘0’ or ‘1’) is expected as compressed test response for a clock cycle, then a ‘1’ is inserted at the corresponding location of the masking data stream. The positions of the X values thus coded in the masking data stream are used for masking the X values.

For this purpose, the TDI data stream and the masking data stream are combined to form a combined test input stream by a masking bit and a test bit being inserted alternately. The tester 501 feeds to the chip 502 the combined test input stream by means of the interface 503 (for example an input/output port of the chip having possibly only one pin).

The test input stream is fed to a test control block 509 by means of the interface 503. The test control block controls the scan test and in this example contains the circuit 504 to be tested, the AND gate 507 for masking the TDO data stream at locations at which an ‘X’ is expected, and the MISR 508. The test control block additionally contains a register 510 for storing the current masking bit, a first clock gate 511 and a second clock gate 512 for dividing the combined test input stream into test data (i.e. the original TDI test data stream) and the masking data stream, and a finite state machine (FSM) 513 for driving the clock gates 511, 512. The finite state machine 513 drives the second clock gate 512 by means of an inverter 514.

The finite state machine 513 outputs an enable signal which is fed to the enable input of the first clock gate 511 and is fed to the inverter 514. The enable signal inverted by the inverter 514 is fed to an enable input of the second clock gate 512.

The output of the first clock gate 511 is coupled to an enable input of the circuit 504 to be tested, such that, when it is activated, it causes a bit to be taken up from the combined test input data stream by the circuit 504 to be tested.

In a similar manner, the output of the second clock gate 512 is coupled to the clock input of the register 510 (implemented as a D-type flip-flop in this example), such that, when it is activated, it causes a bit to be taken up from the combined test input data stream by the register 510.

The finite state machine 513 calculates the enable signal in such a way that, by means of the two clock gates 511, 512, the combined test input stream is split into the test data stream and the masking data stream and the test data stream is fed to the circuit 505 to be tested and the masking data stream is fed to the register 510.

The AND gate 507 is fed the compressed test response from the circuit 505 to be tested and also the current masking bit from the register 510.

The register 510 is a D-type flip-flop, for example. As explained with reference to FIG. 6, the combined test input stream is generated precisely such that the register 510 always stores precisely the masking data for the next (i.e. the current) TDO bit. The TDI bits and masking bits are correspondingly shifted in the combined test input stream depending on the offset between the TDI bits and the (associated) TDO bits.

In an embodiment in which the circuit 504 to be tested has a plurality of TDO outputs, i.e. outputs a plurality of test response bits in parallel, the latter can be masked for example individually by providing a register 510 having a corresponding width for buffer-storing the masking bits.

In the case of an expected ‘X’ value in the compressed test response stream, the register 510 outputs a ‘0’, that is to say that the value ‘0’ is present at the output of the AND gate independently of the compressed test response. The X value is thus masked and the MISR 508 accepts a ‘0’. In the case of an expected deterministic value of the compressed test response, the register 510 feeds a ‘1’ to the AND gate, that is to say that the compressed test response is unmasked and is accepted by the MISR 508 and included in the calculation of the signature.

The signature determined after the test cycle (or else a plurality of such test cycles) by the MISR 508 is output by the MISR 508 via the interface 503 to the tester 501, which uses the determined signature for example for checking a pass/fail criterion for the chip 502.

Instead of an AND gate, any type of gate with a controlling value can be used (e.g. a NAND gate, an OR gate or an NOR gate). The preprocess can be correspondingly adapted for this purpose. Instead of the AND gate 507 for masking X values in the compressed test response stream, it is also possible to use a further clock gate which deactivates the MISR (i.e. the clock signal feed to the MISR 508 is deactivated) as soon as an X value is expected in the compressed test response stream.

In accordance with further embodiments, the security of the chip 502 against attacks can additionally be increased.

In accordance with one embodiment, for example, unauthorized access to a signature is prevented by encrypting the enabling of the masking. By way of example, the register 510 outputs a ‘0’ in its initial state (is initialized with a zero, for example). The clock gate 512 which controls the input clock of the register 510 is enabled (activated) by the finite state machine FSM 513 only if a correct key was fed to the finite state machine beforehand, which key must for example in turn be fed to the chip 502. If the key does not correspond to a reference key stored in the chip 502, the finite state machine 513 does not activate the clock gate and the register 510 is thus not switched, as a result of which the compressed test data stream is permanently masked. If an attacker reads out the signature in this case, said attacker thus merely obtains the initial state thereof.

In a further embodiment, for example, the control line for masking the compressed test response stream, i.e. the line between the outline of the register 510 and the AND gate 510, is connected to an alarm signal. If the masking is deactivated (i.e. the register 510 feeds a ‘1’ to the AND gate 510) but the chip 502 is not in the scan mode (test mode) (but rather e.g. in the user mode or in the infield mode), then an unauthorized use is present since the masking is activated for example by presetting. By way of example, a signal representing the mode of the chip and the output signal of the registers 510 are combined by means of a logic gate to form an alarm signal which, if it is active, deactivates one or more circuits of the chip 502. Misuse of the scan test functionality of the chip 502 can thereby be prevented.

In accordance with a further embodiment, the finite state machine 513 is extended in such a way that an additional output signal of the finite state machine 513 which is combined with the masking data stream constrains an X state for critical values. If, for example, critical elements of the circuit to be tested output information in the direction of MISR 508, then the finite state machine 513 masks this by correspondingly setting the masking data by means of the additional output signal. It is thereby possible to implement on-chip security ensuring that critical information does not pass into the test responses and the signature and is thus also not output via the interface 503. This may be desirable in particular for elements of the circuit to be tested which contain or process cryptographic, secret keys or data. If information is output by such elements for example in specific clock cycles (and would thus influence the signature), then the finite state machine, for these clock cycles, could force the test responses to be masked out and thus additionally safeguard the information. For this purpose, the finite state machine 513 can for example contain a corresponding counter and set the masking data for the corresponding clock cycles accordingly (to the value ‘0’ in this example).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip, comprising:
an interface configured to receive test data and masking data;
a processing component having a plurality of scan chains, wherein each scan chain is configured to generate a test response on the basis of a processing of the test data;
a compression circuit configured to compress the test responses generated by the scan chains to form a compressed test response; and
a signature generating circuit configured to generate a signature on the basis of the compressed test response, depending on whether the masking data specify that the compressed test response is to be masked.

2. The chip of claim 1,
wherein each scan chain is configured to generate a sequence of test responses on the basis of the processing of the test data; and
wherein the compression circuit is configured to compress the sequences of test responses generated by the scan chains to form a sequence of compressed test responses.

3. The chip of claim 2,
wherein the masking data specify which compressed test responses of the sequence of compressed test responses are to be masked; and
wherein the signature generating circuit is configured to generate the signature on the basis of the compressed test responses apart from those compressed test responses of the sequence of compressed test responses which are to be masked.

4. The chip of claim 3,
wherein the signature generating circuit is configured to generate the signature on the basis of the compressed test responses which are not to be masked and predefined values for those compressed test responses of the sequence of compressed test responses which are to be masked.

5. The chip of claim 1, further comprising:
a masking circuit configured to mask the compressed test response if it is to be masked in accordance with the masking data.

6. The chip of claim 5,
wherein masking a test response comprises overwriting the test response with a predefined value.

7. The chip of claim 5,
wherein the chip has a security mode in which the masking circuit is configured to mask the compressed test response independently of the masking data.

8. The chip of claim 7, further comprising:
a security circuit which is configured to deactivate the security mode when a predefined key is input, such that the masking circuit masks the compressed test response depending on the masking data.

9. The chip of claim 7, further comprising:
a detection circuit configured to detect whether the security mode is deactivated even though the chip is not in a test mode, and to output an alarm signal if the security mode is deactivated even though the chip is not in a test mode.

10. The chip of claim 1,
wherein the masking circuit is configured to mask predefined compressed test responses of the compressed test responses independently of the masking data.

11. The chip of claim 1, further comprising:
a control circuit configured to deactivate the processing of a compressed test response for generating a signature if the compressed test response is to be masked.

12. The chip of claim 1,
wherein each test response is a bit.

13. The chip of claim 12,
wherein compressing the test responses is an XOR combination of the test responses, such that the compressed test response is a test response bit.

14. The chip of claim 13,
wherein the masking data comprise, for each test response bit of a sequence of test response bits, a bit which indicates whether the test response bit is to be masked.

15. The chip of claim 1,
wherein the scan chains are configured to process the test data during a plurality of clock cycles of a clock signal and to output a test response for each clock cycle of the clock signal.

16. The chip of claim 15,
wherein the compression circuit is configured to compress, for each clock cycle of the clock signal, the test responses output by the scan chains for the clock cycle to form a compressed test response.

17. The chip of claim 1,
wherein the interface comprises a pin and is configured to receive the test data and masking data via the pin and to output the signature via the pin.

18. A method for testing a processing component of a chip, the method comprising:
receiving test data and masking data by the chip;
generating, by each scan chain of a plurality of scan chains of the processing component, a test response on the basis of a processing of the test data by the scan chain;
compressing the test responses generated by the scan chains to form a compressed test response; and
generating a signature on the basis of the compressed test response depending on whether the masking data specify that the compressed test response is to be masked.

19. The method of claim 18,
wherein each scan chain generates a sequence of test responses on the basis of the processing of the test data; and
wherein the compression circuit compresses the sequences of test responses generated by the scan chains to form a sequence of compressed test responses.

20. The method of claim 18, further comprising:
masking the compressed test response if it is to be masked in accordance with the masking data.
